(19) United States
(12) Patent Application Publication
(10) Pub. No.: US 2013/0214388 A1
(43) Pub. Date: Aug. 22, 2013

(54) Semiconductor Wafer Adapted to Support Transparency in Partial Wafer Processing

(71) Applicant: Balamurugan Subramanian, Plano, TX (US)

(72) Inventor: Balamurugan Subramanian, Plano, TX (US)

(73) Assignee: TEXAS INSTRUMENTS INCORPORATED, Dallas, TX (US)

(21) Appl. No.: 13/400,219

(22) Filed: Feb. 20, 2012

(51) Int. Cl. H01L 23/544; H01L 21/66

(52) U.S. Cl. 257/620; 438/5; 257/E21.529; 257/E23.179

(57) ABSTRACT

A semiconductor wafer is adapted to support partial wafer processing generally transparently to a facility capable of processing a full wafer. The wafer has provided thereon a plurality of semiconductor dice and a plurality of visible reference features. The reference features are positioned among the dice to support a predetermined partitioning of the wafer into partial wafers. The positioning of the reference features may render each partial wafer uniquely visually distinguishable from every other partial wafer. Each partial wafer may contain at least one of the reference features, with the position of each reference feature identified in accordance with a coordinate system of an electronic wafer map. The positioning of the reference features may provide a visual indication of where to cut the wafer to effect the partitioning.

### FIELD

The present work relates generally to processing semiconductor wafers and, more particularly, to processing partial wafers.

### BACKGROUND

A conventional semiconductor (e.g., silicon) wafer contains a plurality of integrated circuit dice. Conventional assembly processes such as pick and place use an electronic wafer map that includes information indicative of die attributes such as the exact location of each die on the wafer, and wafer-level probe test results for each die. The wafer map identifies the exact location of each die using a coordinate system that corresponds to the physical structure of the wafer. The probe test results (die quality) may be expressed as a single bit value, e.g., good (accept) or bad (reject), or a multiple bit value that provides additional information such as good first grade, good second grade, etc. The wafer map includes a plurality of bin numbers to categorize various attributes and/or properties of each die. For example, bin 1 may contain identification of all good first grade dice, bin 2 may contain identification of all good second grade dice, bin 3 may contain identification of all plug dice, bin 4 may contain identification of all bad dice, and bin 5 may contain identification of all edge bad dice. Each die may be assigned to a particular bin based on the results of the probe testing.

At an Assembly/Test (A/T) facility, a wafer undergoes sawing to singulate the dice, and pick and place processing based on the wafer map. The wafer map, which specifies the exact location of all good dice, is used to control an accept/reject function of a conventional pick and place system. Using the wafer map, the pick and place system may be positioned on the good dice without scanning the entire wafer optically to identify the good dice by ink markings as in older systems. Thus, systems that use a wafer map are often referred to as inkless systems.

FIG. 1 shows an example of a conventional semiconductor wafer, where the constituent dice (illustrated as adjacent rectangular shapes in a two-dimensional array) of the wafer are not shown to actual scale, to facilitate clarity of description. As is typical, the wafer contains an orientation marker in the form of a flat edge (at bottom in FIG. 1). Other examples of orientation markers include a wafer flat, a wafer notch, or similar feature. A suitable reference feature (e.g., a mirror area, non-circuit die, or other feature that is readily distinguishable visually from an integrated circuit die) 11 is located in a predetermined area of the wafer. In the example of FIG. 1, the reference feature 11 occupies an area adjacent a lower right edge of the wafer, close to (spaced one edge die away from) the flat edge orientation marker, and encompassing approximately one full die area plus two partial die areas.

A reference die 13 is located leftward adjacent the reference feature 11. The aforementioned coordinate system of the wafer map is defined relative to the location of the reference die 13 on the wafer. The spatial relationship between the reference die 13 and the reference feature 11 is known. The reference feature 11 is readily identifiable by its visually distinct appearance and its known spatial relationship to the flat edge orientation marker. In conventional full wafer processing, the A/T facility equipment uses the reference feature 11 to identify the reference die 13. Such identification of the reference die 13 is conventional.

An A/T facility may be capable of using the wafer map information to process partial wafers, such as wafer halves, wafer quarters, or other fractional wafer parts. This may be advantageous for numerous reasons, some of which follow. The partial wafer may more closely match smaller customer orders. The dice from each partial wafer may be packaged differently than the dice in the other partial wafers. Production cycle times may be reduced by processing multiple partial wafers in parallel. Equipment utilization and flexibility may be improved because the equipment is occupied for less time when processing a partial wafer. As die sizes decrease, the number of dice per wafer increases. This may increase the size of the wafer map for a full wafer beyond the memory capabilities of existing A/T equipment. Silicon dust produced by sawing to singulate the dice introduces difficulties that may be mitigated by sawing only a partial wafer, producing less silicon dust than sawing a full wafer. Some examples of conventional partial wafer processing using a wafer map are described in U.S. Pat. Nos. 7,534,655, 7,015,068, 6,216,055, 6,174,788 and 6,156,625, all of which are incorporated herein by reference.

As compared to processing full wafers using a wafer map, various conventional approaches to partial wafer processing with a wafer map require additional operator participation/input at the A/T facility, and/or integration of customized hardware and/or software into the A/T facility equipment. The requirement of operator participation of course introduces the possibility of operator error. The requirement of integrating customized hardware and/or software solutions may not be easily implementable and/or transportable across different A/T facilities operated by different providers.

It is desirable in view of the foregoing to provide for the capability of processing partial wafers without requiring additional operator participation or integration of customized hardware and/or software solutions.

### BRIEF DESCRIPTION OF THE DRAWINGS

FIG. 1 is a plan view (not to actual scale) of a semiconductor wafer according to the prior art.

FIG. 2 is a plan view similar to FIG. 1, showing a semiconductor wafer according to example embodiments of the present work.

FIG. 3 illustrates an example of cutting the wafer of FIG. 2 to produce two half wafers.

FIG. 4 illustrates an example of cutting the wafer of FIG. 2 to produce four quarter wafers.

FIG. 5 illustrates A/T facility operations supported by the wafer of FIG. 2 according to example embodiments of the present work.

### DETAILED DESCRIPTION

Example embodiments of the present work provide for processing partial wafers using only the conventional equipment and processing techniques already in place at any given A/T facility that uses a wafer map to process full wafers. The partial wafer processing is generally transparent to the A/T facility equipment. If an A/T facility is already capable of processing full wafers using a wafer map, the present work renders that facility capable of processing partial wafers, such as half and quarter wafers, without requiring additional operator participation at the A/T facility, and without requiring integration of customized hardware and/or software solutions into the equipment of the A/T facility.

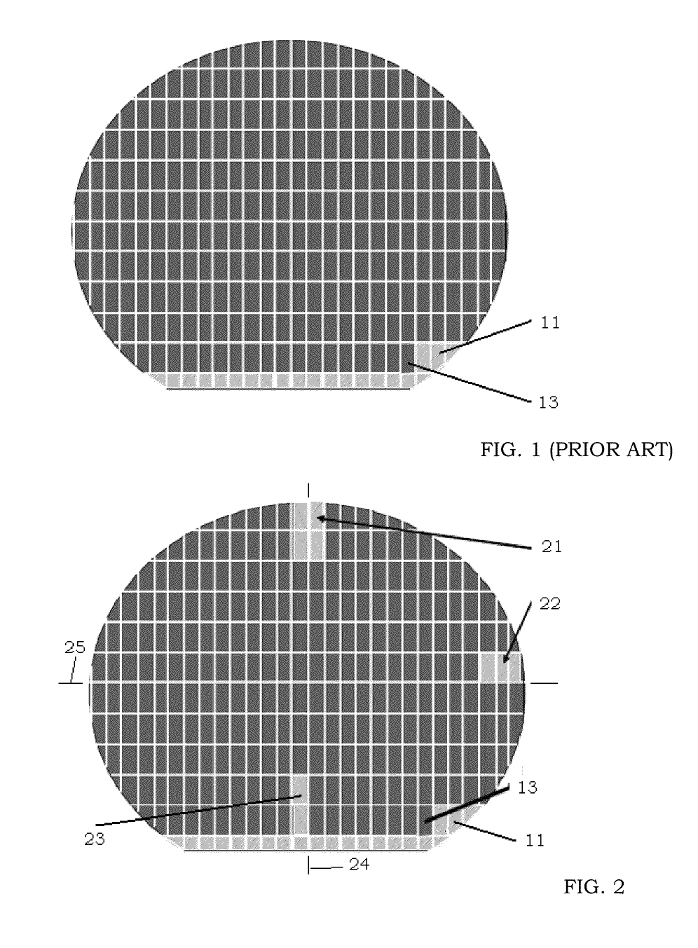

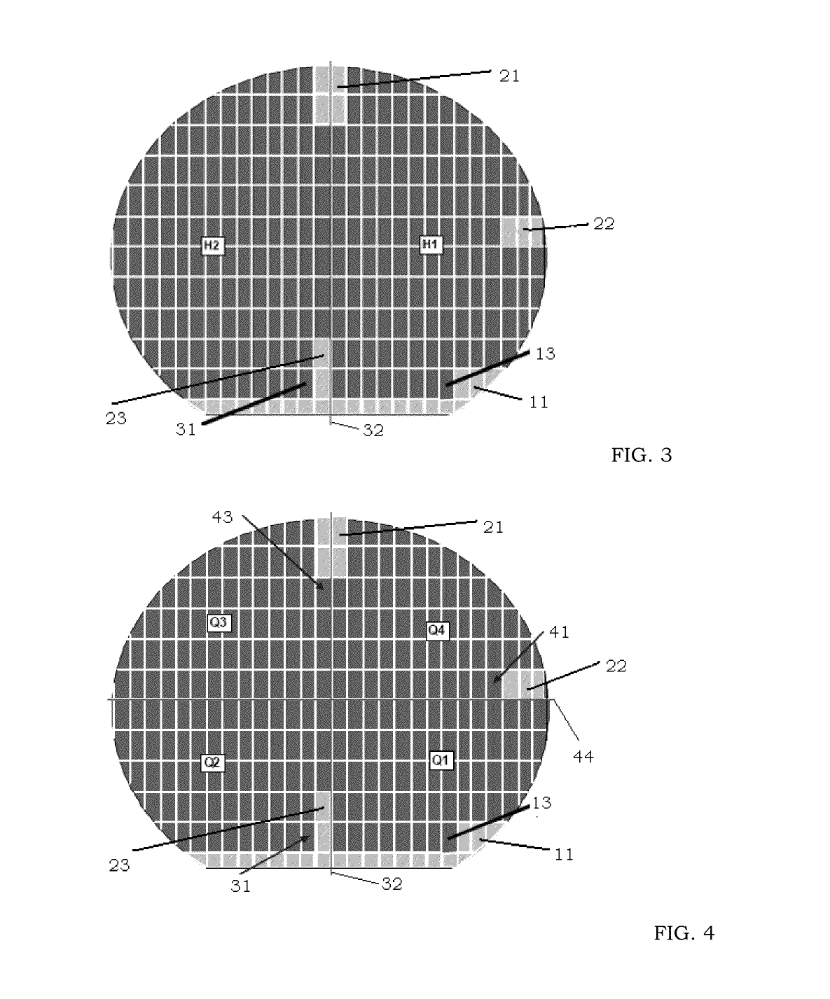

FIG. 2 illustrates a semiconductor (e.g., silicon) wafer according to example embodiments of the present work. As in FIG. 1, the dice in FIG. 2 are not shown to actual scale, to facilitate clarity of description. (The same is true for similarly scaled FIGS. 3-5, described in detail below.) In addition to the reference feature 11 (and reference die 13) provided on the conventional wafer of FIG. 1, the wafer in the FIG. 2 example includes further reference features 21, 22 and 23.

The reference feature 21 is generally centered on a first axis 24 of the wafer. This first axis 24 extends approximately perpendicularly to the flat edge orientation marker and approximately bisects the wafer. In the example shown in FIG. 2, the reference feature 21 encompasses approximately a four-dice area adjacent an edge of the wafer (top edge in FIG. 2) opposite the flat edge orientation marker, and configured in a 2×2 grouping that straddles the first axis 24, with two die areas on each side of the first axis 24.

The reference feature 23 adjoins the first axis 24, with the first axis 24 located between the reference feature 23 and the reference die 13 and reference feature 11. In the example shown in FIG. 2, the reference feature 23 encompasses approximately a two-dice area nearly adjacent (spaced one edge die away from) the flat edge orientation marker, with both die areas adjoining the first axis 24.

The reference feature 22 adjoins a second axis 25 of the wafer. This second axis 25 extends approximately parallel to the flat edge orientation marker and approximately bisects the wafer. The second axis 25 is located between the reference feature 22 and reference die 13, reference feature 11 and reference feature 23. In the example of FIG. 2, the reference feature 22 encompasses approximately a three-dice area adjacent an edge of the wafer (right edge in FIG. 2) across the first axis 24 from the reference feature 23, with all three die areas adjoining the second axis 25.

Some embodiments produce the additional reference features 21-23 of FIG. 2 by suitable reticle control during photomasking operations of the wafer fabrication process. The reference feature 21 may be produced in the form of non-circuit dice by implementing, for example, a suitable reticle shift of two die spaces in two rows of dice. Similarly, the reference feature 23 may be produced in the form of non-circuit dice by implementing, for example, a suitable reticle shift of one die space in two rows of dice, and the reference feature 22 may be produced in the form of non-circuit dice by implementing, for example, a suitable reticle shift of one die space in three columns of dice.

As described in detail below, if a wafer is suitably fabricated with reference features such as described above relative to the example shown in FIG. 2, such a wafer (also referred to herein as a partial-friendly wafer) may be successfully processed, in the form of two half wafers or four quarter wafers, by any A/T facility that is already capable of using wafer map techniques to process the full wafer. The half-wafer or quarter-wafer processing does not require additional operator participation at the A/T facility, or integration of customized hardware and/or software solutions into A/T facility equipment. Note that the partial-friendly wafer of FIG. 2 may be produced entirely in the wafer fabrication process.

Because the first and second axes 24 and 25 are bisecting axes, they coincide approximately with the proper location for saw cuts to bisect the wafer and thereby produce half wafers or quarter wafers. The reference feature 21 and/or the reference feature 23 provides for easy location of a bisecting cut along the first axis 24, and the reference feature 22 provides for easy location of a bisecting cut along the second axis 25. The example of FIG. 3 illustrates a bisecting cut 32 along the first axis 24, which produces two half wafers H1 and H2 as shown. The example of FIG. 4 illustrates an additional bisecting cut 44 along the second axis 25. The combination of the cut 32 and the cut 44 produces four quarter wafers Q1-Q4 as shown. The cut 44 alone, without the cut 32, would of course produce a different pair of half wafers than the H1/H2 pair shown in FIG. 3.

Note from FIG. 3 that the locations of the visually distinguishable reference features 11 and 21-23 render the half wafers H1 and H2 readily visually distinguishable from one another, by human or machine vision, without possibility of misidentification. Thus, each half wafer is uniquely identifiable. The same would be true if the cut 44 were used to produce a different pair of half wafers. It can similarly be seen from FIG. 4 that the locations of the reference features 11 and 21-23 render the quarter wafers Q1-Q4 readily visually distinguishable from one another, by human or machine vision, without possibility of misidentification. Each quarter wafer is thus uniquely identifiable. Note also that the cut 32 along the first axis 24 bisects the reference feature 21 straddling the first axis 24. Accordingly, as shown in FIGS. 3 and 4, both H1 (or Q4) and H2 (or Q3) contain a reference feature that is approximately half the reference feature 21.

Various embodiments provide the reference features at various locations on the wafer such that half wafers and quarter wafers produced from the full wafer are uniquely visually distinguishable from one another, by human or machine vision, without possibility of misidentification. Although half and quarter wafers are presented herein as examples for exposition, various embodiments provide reference features at locations on a wafer suitable to uniquely visually distinguish among partial wafers produced by various wafer partitionings other than halving and quartering.

The reference die 13 is the reference die for the full wafer processing already supported by the A/T facility. The coordinate system of the full wafer map is defined relative to the location of this reference die 13, as is conventional. If the wafers are sawed at 32 to produce half wafers H1 and H2 as in FIG. 3, the reference die 13 is contained in half wafer H1, and the die 31 adjacent the reference feature 23 is the reference die for half wafer H2. In this half wafer example, both of the reference dice 13 and 31 may be identified using the same techniques that the A/T facility already uses to identify the reference die 13 in full wafer processing. The wafer map provided to the A/T facility contains, in an available bin, the coordinates occupied by the reference features 11 and 21-23. If the predetermined spatial relationship between the reference die 31 and the reference feature 23 is provided to the A/T facility, then the reference die 31 may be identified and matched to its coordinates in the wafer map. Thus, the reference die 31 relates the half wafer H2 to the coordinate system of the wafer map, while the reference die 13 relates the half wafer H1 to the coordinate system of the wafer map.

Referring again to FIG. 4, the reference die 13 is contained in quarter wafer Q1, and the reference die 31 is contained in quarter wafer Q2. Furthermore, the die 43 adjacent the reference feature 21 is the reference die for quarter wafer Q3, and the die 41 adjacent the reference feature 22 is the reference die for quarter wafer Q4. In this quarter wafer example, the four reference dice 13, 31, 41 and 43 may be identified using the same techniques that the A/T facility already uses to identify the reference die 13 in full wafer processing. The aforementioned bin in the wafer map contains the coordinates occupied by the reference features 11 and 21-23. If the predetermined spatial relationships between the reference die 31 and the reference feature 23, the reference die 41 and the reference feature 22, and the reference die 43 and the reference feature 21 are made available to the A/T facility, then the reference dice 31, 41 and 43 may be identified and matched to their respective coordinates in the wafer map. Thus, the reference dice 13, 31, 43 and 41 respectively relate the quarter wafers Q1, Q2, Q3 and Q4 to the coordinate system of the wafer map.

The partial wafers produced by wafer partitioning may be identified and uniquely distinguished from one another as described above. The reference dice 13, 31, 41 and 43 of the various partial wafers may be identified as described above, and their associated wafer map coordinates determined. With this information and the full wafer map, any of the partial wafers H1, H2, and Q1-Q4 of FIGS. 3 and 4 may be processed in the same fashion as a full wafer, using the already-known portion of the full wafer map that corresponds to that partial wafer.

The above-described correspondences between partial wafers and reference dice used for processing those partial wafers are examples, and are not exclusive. Because each partial wafer is uniquely identifiable, the portion of the wafer map to use for processing a given partial wafer is also known. With that information for a partial wafer, any die that may be identified using a reference feature contained on that partial wafer may be used as a reference die to relate the partial wafer to the coordinate system of the wafer map. Note in this regard that either cut 32 of FIG. 3 or cut 44 of FIG. 4 produces two half wafers, each of which contains at least two of the illustrated reference features.

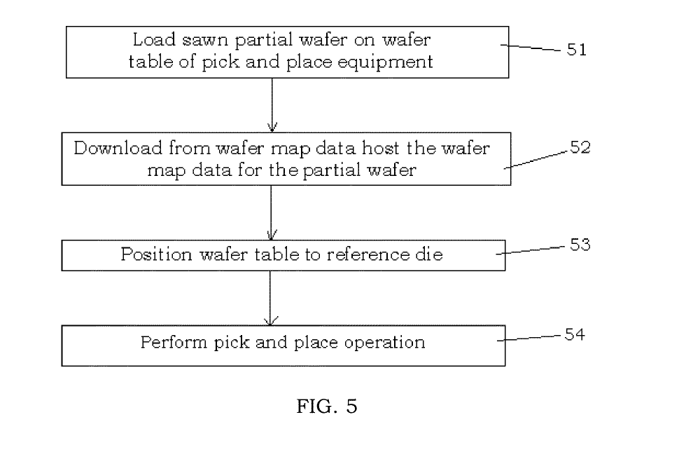

FIG. 5 illustrates operations that may be performed according to example embodiments of the present work. At 51, after the partial wafer has been sawed to singulate its dice, the singulated partial wafer is loaded on the wafer table of the A/T facility's pick and place equipment. At 52, the portion of the wafer map data corresponding to the partial wafer (including the coordinates of the reference feature) is downloaded from the A/T facility's wafer map data host. In some embodiments, the wafer map data host contains the wafer map for the full wafer. The wafer table is positioned to the reference die of the partial wafer at 53, and the pick and place operation proceeds at 54, using the portion of the wafer map downloaded at 52.

Various advantages associated with the present work are apparent from the foregoing description. Further merits of the present work are mentioned here briefly. The partial wafers produced by partitioning a single wafer may be successfully processed by respectively different A/T facilities. Wafers larger than the largest wafer size accommodated by an A/T facility may be partitioned into partial wafers small enough to be accommodated and successfully processed by the facility.

Although example embodiments of the present work have been described above in detail, this does not limit the scope of the work, which can be practiced in a variety of embodiments.

1. A semiconductor wafer adapted to support partial wafer processing, comprising:
a plurality of semiconductor dice; and
a plurality of visible reference features;
wherein said reference features are respectively positioned among said dice at a plurality of predetermined locations to support a predetermined partitioning of the wafer into partial wafers such that said reference features render each partial wafer uniquely visually distinguishable from every other partial wafer.

2. The wafer of claim 1, wherein said predetermined locations are identified, in accordance with a coordinate system, in an electronic wafer map that also contains probe test results for said dice, and wherein said reference features at said predetermined locations support the predetermined partitioning such that each partial wafer contains one of said reference features.

3. The wafer of claim 2, wherein the reference features contained by the partial wafers are respectively adjacent reference dice on the partial wafers such that each partial wafer contains a reference die, wherein the coordinate system of the electronic wafer map is defined relative to one said reference die, and wherein the remainder of said reference dice relate the associated partial wafers into the coordinate system of the wafer map.

4. The wafer of claim 3, wherein said reference features at said predetermined locations support the predetermined partitioning by providing a visual indication of where to cut the wafer to effect the predetermined partitioning.

5. The wafer of claim 2, wherein said reference features at said predetermined locations support the predetermined partitioning by providing a visual indication of where to cut the wafer to effect the predetermined partitioning.

6. The wafer of claim 1, wherein said reference features at said predetermined locations support the predetermined partitioning by providing a visual indication of where to cut the wafer to effect the predetermined partitioning.

7. The wafer of claim 1, wherein the partial wafers are half wafers.

8. The wafer of claim 1, wherein the partial wafers are quarter wafers.

9. A semiconductor wafer adapted to support partial wafer processing, comprising:
a plurality of semiconductor dice; and
a plurality of visible reference features;
wherein said reference features are respectively positioned among said dice at a plurality of predetermined locations identified, in accordance with a coordinate system, in an electronic wafer map that also contains probe test results for said dice, and wherein said predetermined reference features at said predetermined locations support a predetermined partitioning of the wafer into partial wafers such that each partial wafer contains one of said reference features.

10. The wafer of claim 9, wherein the reference features include non-circuit dice.

11. A semiconductor wafer adapted to support partial wafer processing, comprising:
a plurality of semiconductor dice; and
a plurality of visible reference features;
wherein said reference features are respectively positioned among said dice at a plurality of predetermined locations to support a predetermined partitioning of the wafer into partial wafers by providing a visual indication of where to cut the wafer to effect the predetermined partitioning.

12. A method of producing a semiconductor wafer adapted to support partial wafer processing, comprising:
providing on the wafer a plurality of semiconductor dice; and
providing on the wafer a plurality of visible reference features;
wherein said reference features are respectively positioned among said dice at a plurality of predetermined locations to support a predetermined partitioning of the wafer into partial wafers such that said reference features render each partial wafer uniquely visually distinguishable from every other partial wafer.

13. The method of claim 12, wherein said predetermined locations are identified, in accordance with a coordinate system, in an electronic wafer map that also contains probe test results for said dice, and wherein said reference features at said predetermined locations support the predetermined partitioning such that each partial wafer contains one of said reference features.

14. The method of claim 13, wherein the reference features contained by the partial wafers are respectively adjacent reference dice on the partial wafers such that each partial wafer contains a reference die, wherein the coordinate system of the electronic wafer map is defined relative to one said reference die, and wherein the remainder of said reference dice relate the associated partial wafers into the coordinate system of the wafer map.

15. The method of claim 14, wherein said reference features at said predetermined locations support the predetermined partitioning by providing a visual indication of where to cut the wafer to effect the predetermined partitioning.

16. The method of claim 13, wherein said reference features at said predetermined locations support the predetermined partitioning by providing a visual indication of where to cut the wafer to effect the predetermined partitioning.

17. The method of claim 12, wherein said reference features at said predetermined locations support the predetermined partitioning by providing a visual indication of where to cut the wafer to effect the predetermined partitioning.

18. A method of producing a semiconductor wafer adapted to support partial wafer processing, comprising:
providing on the wafer a plurality of semiconductor dice; and
providing on the wafer a plurality of visible reference features;
wherein said reference features are respectively positioned among said dice at a plurality of predetermined locations identified, in accordance with a coordinate system, in an electronic wafer map that also contains probe test results for said dice, and wherein said predetermined reference features at said predetermined locations support a predetermined partitioning of the wafer into partial wafers such that each partial wafer contains one of said reference features.

19. A method of producing a semiconductor wafer adapted to support partial wafer processing, comprising:
providing on the wafer a plurality of semiconductor dice; and
providing on the wafer a plurality of visible reference features;
wherein said reference features are respectively positioned among said dice at a plurality of predetermined locations to support a predetermined partitioning of the wafer into partial wafers by providing a visual indication of where to cut the wafer to effect the predetermined partitioning.

20. A method for processing any of a plurality of partial semiconductor wafers that have been partitioned from a single full semiconductor wafer, comprising:
providing an electronic wafer map that contains probe test results for constituent semiconductor dice of the full wafer; and
for any of the partial wafers, and regardless of which of the partial wafers,
providing the partial wafer with the constituent semiconductor dice thereof singulated,
accessing a portion of the wafer map associated with the dice of the partial wafer,
using a visible reference feature located among the singulated dice of the partial wafer to position pick and place equipment to a reference die that relates the partial wafer to a coordinate system of the wafer map, and
with the pick and place equipment positioned to the reference die, performing pick and place operations with respect to the partial wafer using said portion of the wafer map.
